(19) United States
(12) Patent Application Publication
(10) Pub. No.: US 2024/0196748 A1
(43) Pub. Date: Jun. 13, 2024

(54) THERMOELECTRIC CONVERSION UNIT AND METHOD OF USING SAME

(71) Applicant: Panasonic Intellectual Property Management Co., Ltd., Osaka (JP)

(72) Inventor: HIROMASA TAMAKI, Osaka (JP)

(21) Appl. No.: 18/585,015

(22) Filed: Feb. 22, 2024

Related U.S. Application Data
(63) Continuation of application No. PCT/JP2022/030057, filed on Aug. 5, 2022.

(30) Foreign Application Priority Data
Sep. 9, 2021 (JP) 2021-146666

(51) Int. Cl. H10N 10/17; F01N 5/02; H10N 10/13

(52) U.S. Cl. CPC H10N 10/17; H10N 10/13; F01N 5/025

(57) ABSTRACT

A thermoelectric conversion unit including a pair of first fluid flow passage parts facing each other through which a first fluid flows; a second fluid flow passage part disposed between the first fluid flow passage parts and through which a second fluid having a higher temperature than the first fluid flows; a pair of thermoelectric modules each disposed between a corresponding one of the first fluid flow passage parts and the second fluid flow passage part and generating electromotive force based on a temperature difference between the first fluid and second fluid; and a pair of magnetic body parts disposed inside of or on a surface of the first fluid flow passage parts, in which each of the magnetic body parts has a magnetic body, and the magnetic bodies are disposed so that different magnetic poles face each other, and generate magnetic force pulling the magnetic bodies toward each other.

### BACKGROUND

### 1. Technical Field

The present disclosure relates to a thermoelectric conversion unit that generates electromotive force on the basis of a temperature difference and a method of using the thermoelectric conversion unit.

### 2. Description of the Related Art

A conventional thermoelectric conversion unit (see, for example, Japanese Unexamined Patent Application Publication No. 10-213360 and Japanese Unexamined Patent Application Publication No. 2006-86210) includes a low-temperature fluid flow passage part through which a low-temperature fluid flows, a high-temperature fluid flow passage part through which a high-temperature fluid flows, and a thermoelectric module that is disposed between the low-temperature fluid flow passage part and the high-temperature fluid flow passage part. The thermoelectric module generates electromotive force on the basis of a temperature difference between the high-temperature fluid that flows through the high-temperature fluid flow passage part and the low-temperature fluid that flows through the low-temperature fluid flow passage part by utilizing the Seebeck effect.

In the conventional thermoelectric conversion unit, a magnet is disposed in the low-temperature fluid flow passage part and the high-temperature fluid flow passage part. Magnetic force is generated between a magnet (hereinafter referred to as a “first magnet”) that is disposed in the low-temperature fluid flow passage part and a magnet (hereinafter referred to as a “second magnet”) that is disposed in the high-temperature fluid flow passage part so that the magnets are attracted to each other, and thereby the low-temperature fluid flow passage part and the high-temperature fluid flow passage part are fixed to each other.

### SUMMARY

However, in the conventional thermoelectric conversion unit, heat of the high-temperature fluid that flows through the high-temperature fluid flow passage part dissipates through the second magnet. This undesirably decreases efficiency of heat transfer from the high-temperature fluid to the thermoelectric module.

Heat of the high-temperature fluid that flows through the high-temperature fluid flow passage part transfers to the second magnet, and thereby a temperature of the second magnet rises. This decreases a magnetic moment of the second magnet, thereby making thermal contact between the low-temperature fluid flow passage part and the thermoelectric module and thermal contact between the high-temperature fluid flow passage part and the thermoelectric module insufficient. As a result, power generation efficiency of the thermoelectric module undesirably decreases.

One non-limiting and exemplary embodiment provides a thermoelectric conversion unit that can increase power generation efficiency and a method of using the thermoelectric conversion unit.

In one general aspect, the techniques disclosed here feature a thermoelectric conversion unit including: a pair of first fluid flow passage parts that face each other and through which a first fluid flows; a second fluid flow passage part that is disposed between the pair of first fluid flow passage parts and through which a second fluid having a higher temperature than the first fluid flows; a pair of thermoelectric modules cach of which is disposed between a corresponding one of the first fluid flow passage parts that constitute the pair of first fluid flow passage parts and the second fluid flow passage part and generates electromotive force on the basis of a temperature difference between the first fluid and the second fluid; and a pair of magnetic body parts that are disposed inside of or on a surface of the pair of first fluid flow passage parts, respectively, in which each of the magnetic body parts has a magnetic body, and the magnetic bodies of the pair of magnetic body parts are disposed so that different magnetic poles face each other, and generate magnetic force that pulls the magnetic bodies toward each other.

According to a thermoelectric conversion unit and others according to one aspect of the present disclosure, power generation efficiency can be increased.

It should be noted that general or specific embodiments may be implemented as an apparatus, a method, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a perspective view illustrating a thermoelectric conversion unit according to Embodiment 1;

FIG. 2 is an exploded perspective view illustrating the thermoelectric conversion unit according to Embodiment 1;

FIG. 3 is a cross-sectional view of a substantial part of the thermoelectric conversion unit according to Embodiment 1 taken along line III-III of FIG. 2;

FIG. 4 is a view for explaining a configuration of a thermoelectric generator according to Embodiment 1;

FIG. 5 is a plan view illustrating a thermoelectric generator according to Embodiment 1;

FIG. 6 is a cross-sectional view of a substantial part of a thermoelectric conversion unit according to a modification of Embodiment 1;

FIG. 7 is a schematic view for explaining a configuration of a thermoelectric module according to the modification of Embodiment 1;

FIG. 8 is a perspective view illustrating a thermoelectric conversion unit according to Embodiment 2;

FIG. 9 is a cross-sectional view of a substantial part of the thermoelectric conversion unit according to Embodiment 2 taken along line IX-IX of FIG. 8;

FIG. 10 is a perspective view illustrating a thermoelectric conversion unit according to Modification 1 of Embodiment 2;

FIG. 11 is a perspective view illustrating a thermoelectric conversion unit according to Modification 2 of Embodiment 2;

FIG. 12 is a perspective view illustrating a thermoelectric conversion unit according to Embodiment 3;

FIG. 13 is a cross-sectional view of a substantial part of the thermoelectric conversion unit according to Embodiment 3 taken along line XIII-XIII of FIG. 12;

FIG. 14 is a cross-sectional view of a substantial part of a thermoelectric conversion unit according to a modification of Embodiment 3; and

FIG. 15 is a cross-sectional view of a substantial part of a thermoelectric conversion unit according to Embodiment 4.

### DETAILED DESCRIPTIONS

A thermoelectric conversion unit according to one aspect of the present disclosure includes a pair of first fluid flow passage parts that face each other and through which a first fluid flows; a second fluid flow passage part that is disposed between the pair of first fluid flow passage parts and through which a second fluid having a higher temperature than the first fluid flows; a pair of thermoelectric modules each of which is disposed between a corresponding one of the first fluid flow passage parts that constitute the pair of first fluid flow passage parts and the second fluid flow passage part and generates electromotive force on the basis of a temperature difference between the first fluid and the second fluid; and a pair of magnetic body parts that are disposed inside of or on a surface of the pair of first fluid flow passage parts, respectively, in which each of the magnetic body parts has a magnetic body, and the magnetic bodies of the pair of magnetic body parts are disposed so that different magnetic poles face each other, and generate magnetic force that pulls the magnetic bodies toward each other.

According to this aspect, the pair of magnetic body parts are disposed in the pair of first fluid flow passage parts, respectively. Since the magnetic bodies of the magnetic body parts are cooled by the first fluid having a relatively low temperature that flows through the first fluid flow passage parts, a rise in temperature of the magnetic bodies can be suppressed. This can suppress a decrease in magnetic moments of the magnetic bodies and promote thermal contact between the first fluid flow passage parts and the thermoelectric modules, thereby increasing power generation efficiency in the pair of thermoelectric modules. The pair of first fluid flow passage parts, the second fluid flow passage part, and the pair of thermoelectric modules are fixed to each other by utilizing magnetic force that pulls the magnetic bodies of the pair of magnetic body parts toward each other. This produces flexibility in relative positional relationship among the pair of first fluid flow passage parts, the second fluid flow passage part, and the pair of thermoelectric modules. As a result, for example, even in a case where external vibration, thermal shock, or the like is applied to the thermoelectric conversion unit, the pair of first fluid flow passage parts, the second fluid flow passage part, and the pair of thermoelectric modules are displaced relative to each other. This can absorb stress applied to the pair of thermoelectric modules, thereby suppressing damage of the pair of thermoelectric modules.

The thermoelectric conversion unit may be configured to further include a cylindrical part that divides at least an inside of the second fluid flow passage part along a predetermined direction pointing from one of the first fluid flow passage parts to the other one of the first fluid flow passage parts, and the magnetic bodies of the pair of magnetic body parts may generate the magnetic force in the cylindrical part.

According to this aspect, the magnetic bodies of the pair of magnetic body parts can generate magnetic force that pulls the magnetic bodies toward each other in the cylindrical part.

The thermoelectric conversion unit may be configured such that the magnetic bodies of the pair of magnetic body parts are disposed in the cylindrical part.

According to this aspect, the magnetic bodies of the pair of magnetic body parts can be disposed in proximity to each other in the cylindrical part.

The thermoelectric conversion unit may be configured such that cylindrical parts are provided as the cylindrical part; and the cylindrical parts are substantially symmetrically disposed about a center of the second fluid flow passage part.

According to this aspect, a pressure which each of the thermoelectric modules receives from a corresponding one of the first fluid flow passage parts can be made substantially uniform.

The thermoelectric conversion unit may be configured such that each of the first fluid flow passage parts has a groove part that protrudes toward the cylindrical part; and each of the magnetic bodies of the pair of magnetic body parts is disposed in the groove part so as to be located on a surface of a corresponding one of the first fluid flow passage parts.

According to this aspect, the magnetic body can be compactly disposed in the groove part.

The thermoelectric conversion unit may be configured such that each of the first fluid flow passage parts has an opening opened toward the cylindrical part; and each of the magnetic body parts is inserted into the opening.

According to this aspect, the magnetic body parts can be easily disposed in the first fluid flow passage parts by inserting the magnetic body parts into the opening.

The thermoelectric conversion unit may be configured such that each of the magnetic body parts has a bar shape and extends along the predetermined direction; the magnetic body is disposed at one end part of each of the magnetic body parts; and the other end part of each of the magnetic body parts is engaged with the opening.

According to this aspect, the other end part of each of the magnetic body parts is engaged with the opening, and therefore when the magnetic bodies of the pair of magnetic body parts generate magnetic force that pulls the magnetic bodies toward each other, the pair of first fluid flow passage parts, the second fluid flow passage part, and the pair of thermoelectric modules can be easily fixed to each other.

The thermoelectric conversion unit may be configured such that one pair of openings are provided as the opening; each of the magnetic body parts has a pressing part that extends along a direction that crosses the predetermined direction and a pair of insertion parts that extend from both end parts of the pressing part along the predetermined direction and face each other; the pair of insertion parts are inserted into the pair of openings, respectively; the magnetic body is disposed in each of the insertion parts; and the pressing part presses a corresponding one of the first fluid flow passage parts toward a corresponding one of the thermoelectric modules.

According to this aspect, a large contact area between the pressing part of the magnetic body part and the first fluid flow passage part can be secured, and therefore a surface pressure applied from the first fluid flow passage part to the thermoelectric module can be kept substantially uniform. This can suppress occurrence of stress unevenness in the thermoelectric module.

The thermoelectric conversion unit may be configured such that each of the thermoelectric modules has a through-hole that passes through the thermoelectric module; and a corresponding one of the magnetic body parts, the cylindrical part, or the corresponding one of the magnetic body parts and the cylindrical part is/are disposed in the through-hole.

According to this aspect, a corresponding one of the magnetic body parts, the cylindrical part, or the corresponding one of the magnetic body parts and the cylindrical part can be disposed in the through-hole of the thermoelectric module.

The thermoelectric conversion unit may be configured such that as the pair of thermoelectric modules, pairs of thermoelectric modules are stacked in the predetermined direction.

According to this aspect, the thermoelectric conversion unit can be made compact.

The thermoelectric conversion unit may be configured such that at least a part of an inner circumferential surface of the cylindrical part is covered with a heat insulating member.

According to this aspect, heat of the second fluid having a relatively high temperature that flows through the second fluid flow passage part is made less likely to transfer to the magnetic bodies by the heat insulating member. This can suppress a rise in temperature of the magnetic bodies and can suppress a decrease in magnetic moment of the magnetic bodies.

The thermoelectric conversion unit may be configured such that the heat insulating member is made of at least one of glass wool, a ceramic, or a resin.

According to this aspect, absorption of magnetic force of the magnetic bodies by the heat insulating member can be suppressed.

The thermoelectric conversion unit may be configured such that the second fluid flow passage part has a heat transfer fin having a pin shape disposed along the predetermined direction, heat transfer fins having a plate shape that face each other along the predetermined direction, or the heat transfer fin having a pin shape and the heat transfer fins having a plate shape.

According to this aspect, heat of the second fluid that flows through the second fluid flow passage part can be efficiently transferred to the thermoelectric modules through the heat transfer fin having a pin shape and/or the heat transfer fins having a plate shape.

The thermoelectric conversion unit may be configured such that each of the thermoelectric modules has a first main surface that faces a corresponding one of the first fluid flow passage parts and a second main surface that faces the second fluid flow passage part; and PoS satisfies 10 kPa≤PoS≤1 MPa where PoS is a pressure which the first main surface of each of the thermoelectric modules receives from a corresponding one of the first fluid flow passage parts.

According to this aspect, thermal contact between the first fluid flow passage parts and the thermoelectric modules can be effectively promoted.

The thermoelectric conversion unit may be configured such that each of the thermoelectric modules has a first main surface that faces a corresponding one of the first fluid flow passage parts and a second main surface that faces the second fluid flow passage part; and a heat transfer member is interposed between each of the first fluid flow passage parts and the first main surface, between the second fluid flow passage part and the second main surface, or between each of the first fluid flow passage parts and the first main surface and between the second fluid flow passage part and the second main surface.

According to this aspect, heat-transfer efficiency from the first fluid flow passage part to the thermoelectric module and/or heat-transfer efficiency from the second fluid flow passage part to the thermoelectric module can be increased.

The thermoelectric conversion unit may be configured such that the heat transfer member is a thermally-conductive sheet, thermally-conductive grease, or the thermally-conductive sheet and the thermally-conductive grease.

According to this aspect, the heat transfer member can be easily interposed in a gap between the first fluid flow passage part and the first main surface of the thermoelectric module and/or a gap between the second fluid flow passage part and the second main surface of the thermoelectric module.

The thermoelectric conversion unit may be configured such that the magnetic body is a permanent magnet.

According to this aspect, magnetic force that pulls the magnetic bodies of the pair of magnetic body parts toward each other can be increased.

The thermoelectric conversion unit may be configured such that the permanent magnet is at least one of a samarium-cobalt magnet, a neodymium magnet, an alnico magnet, or a ferrite magnet.

According to this aspect, magnetic force that pulls the magnetic bodies of the pair of magnetic body parts toward each other can be further increased.

A method of using a thermoelectric conversion unit according to an aspect of the present disclosure is a method of using a thermoelectric conversion unit including: a pair of first fluid flow passage parts that face each other and through which a first fluid flows; a second fluid flow passage part that is disposed between the pair of first fluid flow passage parts and through which a second fluid having a higher temperature than the first fluid flows; a pair of thermoelectric modules each of which is disposed between a corresponding one of the first fluid flow passage parts that constitute the pair of first fluid flow passage parts and the second fluid flow passage part and generates electromotive force on the basis of a temperature difference between the first fluid and the second fluid; and a pair of magnetic body parts that are disposed inside of or on a surface of the pair of first fluid flow passage parts, respectively, each of the magnetic body parts having a magnetic body, and the magnetic bodies of the pair of magnetic body parts being disposed so that different magnetic poles face each other, and generate magnetic force that pulls the magnetic bodies toward each other, and the method includes transferring heat of the second fluid to each of the thermoelectric modules; and generating the electromotive force on the basis of the temperature difference by giving the temperature difference to each of the thermoelectric modules.

According to this aspect, the pair of magnetic body parts are disposed in the pair of first fluid flow passage parts, respectively. Since the magnetic bodies of the magnetic body parts are cooled by the first fluid having a relatively low temperature that flows through the first fluid flow passage parts, a rise in temperature of the magnetic bodies can be suppressed. This can suppress a decrease in magnetic moments of the magnetic bodies and promote thermal contact between the first fluid flow passage parts and the thermoelectric modules, thereby increasing power generation efficiency in the pair of thermoelectric modules. The pair of first fluid flow passage parts, the second fluid flow passage part, and the pair of thermoelectric modules are fixed to each other by utilizing magnetic force that pulls the magnetic bodies of the pair of magnetic body parts toward each other. This produces flexibility in relative positional relationship among the pair of first fluid flow passage parts, the second fluid flow passage part, and the pair of thermoelectric modules. As a result, for example, even in a case where external vibration, thermal shock, or the like is applied to the thermoelectric conversion unit, the pair of first fluid flow passage parts, the second fluid flow passage part, and the pair of thermoelectric modules are displaced relative to each other. This can absorb stress applied to the pair of thermoelectric modules, thereby suppressing damage of the pair of thermoelectric modules.

Note that these general or specific aspects may be realized by an apparatus, a method, or any combination thereof.

Embodiments are described below with reference to the drawings.

Note that embodiments described below are general or specific examples. Numerical values, shapes, materials, constituent elements, the way in which the constituent elements are disposed and connected, steps, the order of steps, and the like in the embodiments below are examples and do not limit the claims. Among constituent elements in the embodiments below, constituent elements that are not described in independent claims indicating highest concepts are described as optional constituent elements. Each drawing is not necessarily strict illustration. In the drawings, substantially identical constituent elements are given identical reference signs, and repeated description thereof is omitted or simplified.

### Embodiment 1

### 1-1. Overall Configuration of Thermoelectric Conversion Unit

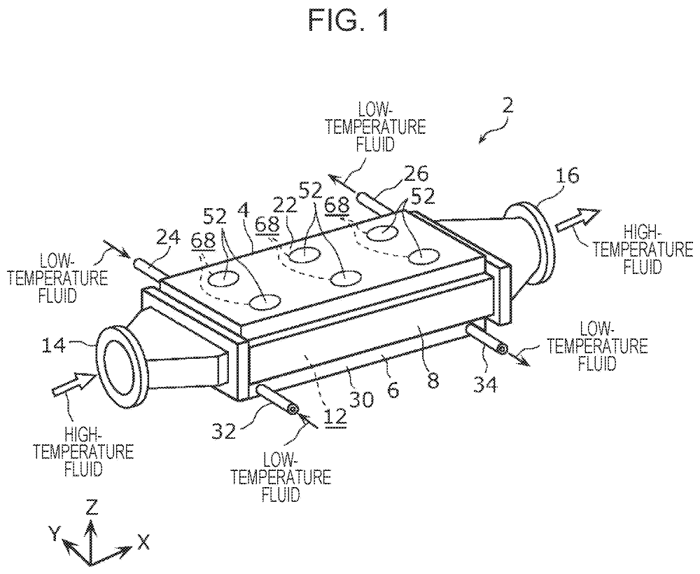

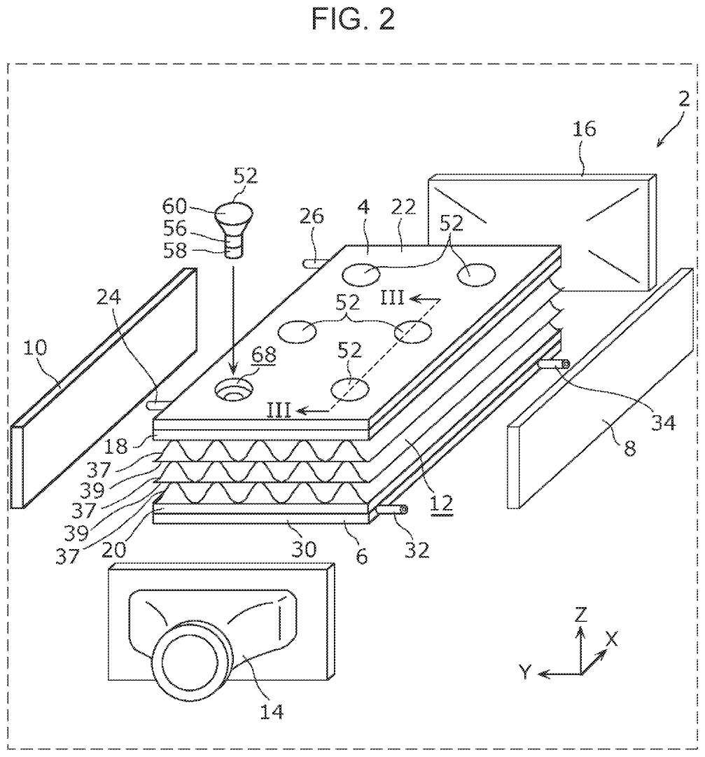

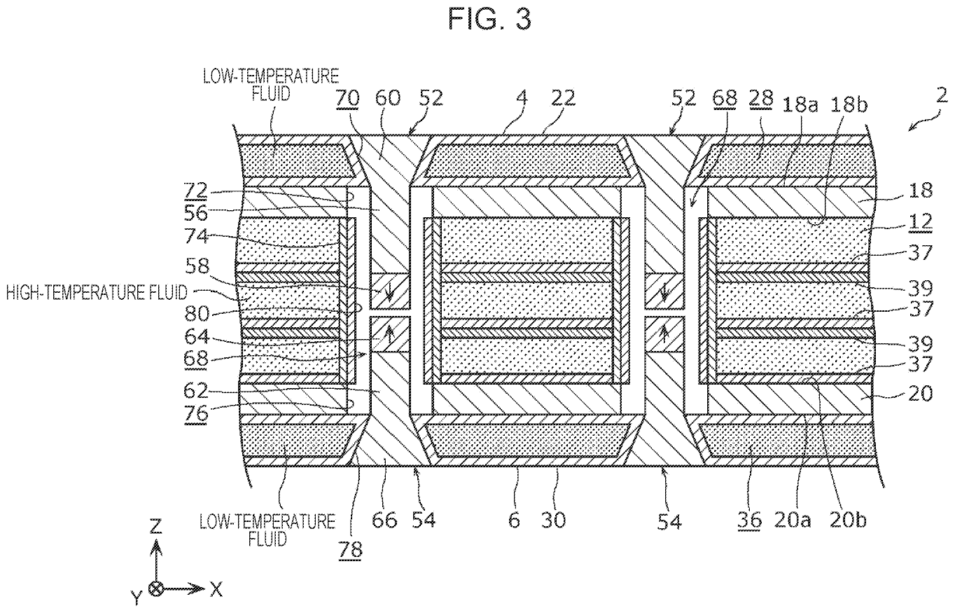

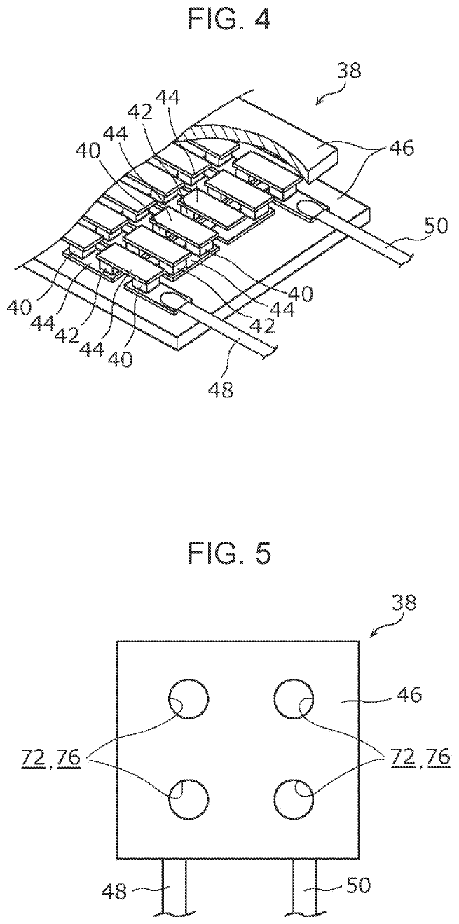

First, an overall configuration of the thermoelectric conversion unit 2 according to Embodiment 1 is described with reference to FIGS. 1 to 4. FIG. 1 is a perspective view illustrating a thermoelectric conversion unit 2 according to Embodiment 1. FIG. 2 is an exploded perspective view illustrating the thermoelectric conversion unit 2 according to Embodiment 1. FIG. 3 is a cross-sectional view of a substantial part of the thermoelectric conversion unit 2 according to Embodiment 1 taken along line III-III of FIG. 2. FIG. 4 is a view for explaining a configuration of a thermoelectric generator 38 according to Embodiment 1.

Note that in FIGS. 1 to 3, a front-rear direction of the thermoelectric conversion unit 2 is referred to as an X-axis direction, a left-right direction of the thermoelectric conversion unit 2 is referred to as a Y-axis direction, and an up-down direction of the thermoelectric conversion unit 2 is referred to as a Z-axis direction.

The thermoelectric conversion unit 2 is, for example, a thermoelectric conversion unit used for power generation using thermal energy of exhaust gas discharged from an engine mounted on a vehicle.

As illustrated in FIGS. 1 to 3, the thermoelectric conversion unit 2 includes a pair of low-temperature fluid flow passage parts 4 and 6 (an example of a pair of first fluid flow passage parts), a pair of side surface parts 8 and 10, a high-temperature fluid flow passage part 12 (an example of a second fluid flow passage part), a high-temperature fluid introducing part 14, a high-temperature fluid discharging part 16, and a pair of thermoelectric modules 18 and 20.

The pair of low-temperature fluid flow passage parts 4 and 6 are disposed apart from each other in the up-down direction (the Z-axis direction) so as to face each other.

The low-temperature fluid flow passage part 4 on the upper side has a housing 22 having a flat hollow rectangular parallelepiped shape, and pipe-shaped low-temperature fluid introducing part 24 and low-temperature fluid discharging part 26 that protrude toward an outside from a side surface of the housing 22. The housing 22 is, for example, made of stainless steel or the like. As illustrated in FIG. 3, a low-temperature fluid flow passage 28 through which a low-temperature fluid (an example of a first fluid) flows is provided in the housing 22. The low-temperature fluid is, for example, a cool water, cool air, or the like having a lower temperature than a high-temperature fluid (described later). The low-temperature fluid introducing part 24 and the low-temperature fluid discharging part 26 are disposed apart from each other in the front-rear direction (the X-axis direction) and are communicated with the low-temperature fluid flow passage 28 of the housing 22. The low-temperature fluid flows into the low-temperature fluid flow passage 28 of the housing 22 through the low-temperature fluid introducing part 24 and is discharged to an outside through the low-temperature fluid discharging part 26 after flowing through the low-temperature fluid flow passage 28.

The low-temperature fluid flow passage part 6 on the lower side has a housing 30 having a flat hollow rectangular parallelepiped shape, and pipe-shaped low-temperature fluid introducing part 32 and low-temperature fluid discharging part 34 that protrude toward an outside from a side surface of the housing 30. The housing 30 is, for example, made of stainless steel or the like. As illustrated in FIG. 3, a low-temperature fluid flow passage 36 through which a low-temperature fluid flows is provided in the housing 30. The low-temperature fluid introducing part 32 and the low-temperature fluid discharging part 34 are disposed apart from each other in the front-rear direction and are communicated with the low-temperature fluid flow passage 36 of the housing 30. The low-temperature fluid flows into the low-temperature fluid flow passage 36 of the housing 30 through the low-temperature fluid introducing part 32 and is discharged to an outside through the low-temperature fluid discharging part 34 after flowing through the low-temperature fluid flow passage 36. Note that the low-temperature fluid that flows through the low-temperature fluid flow passage 36 may be the same as the low-temperature fluid that flows through the low-temperature fluid flow passage 28 or may be different from the low-temperature fluid that flows through the low-temperature fluid flow passage 28.

As illustrated in FIGS. 1 and 2, the pair of side surface parts 8 and 10 are disposed apart from each other in the left-right direction (the Y-axis direction) so as to face cach other. That is, the pair of side surface parts 8 and 10 are disposed so as to cover, from sides in the left-right direction, the high-temperature fluid flow passage part 12 (described later) disposed between the pair of low-temperature fluid flow passage parts 4 and 6. Each of the side surface parts 8 and 10 has a rectangular flat plate shape.

As illustrated in FIGS. 2 and 3, the high-temperature fluid flow passage part 12 is disposed between the pair of low-temperature fluid flow passage parts 4 and 6. Specifically, the high-temperature fluid flow passage part 12 is defined by a space surrounded by the pair of low-temperature fluid flow passage parts 4 and 6 and the pair of side surface parts 8 and 10. The high-temperature fluid flow passage part 12 functions as a high-temperature fluid flow passage through which a high-temperature fluid (an example of a second fluid) flows. The high-temperature fluid is a fluid that has a higher temperature than the low-temperature fluid and is, for example, exhaust gas discharged from an engine mounted on a vehicle.

In the high-temperature fluid flow passage part 12, heat transfer fins 37 having a plate shape (a corrugated plate shape) and heat transfer fins 39 having a plate shape (a flat plate shape) are provided. The heat transfer fins 37 and 39 are alternately arranged along a direction (the Z-axis direction) (hereinafter referred to as a “predetermined direction”) pointing from the low-temperature fluid flow passage part 4 on the upper side to the low-temperature fluid flow passage part 6 on the lower side so as to face each other. An inner part and a surface of each of the heat transfer fins 37 and 39 are made of different materials. The inner part of each of the heat transfer fins 37 and 39 is made of a material having high thermal conductivity such as copper, a copper alloy, aluminum, an aluminum alloy, stainless steel, or a ceramic. The surface of each of the heat transfer fins 37 and 39 is coated with a metal having high corrosion resistance such as nickel, a nickel alloy, chromium, or a chromium alloy. To coat the surface of each of the heat transfer fins 37 and 39, a method such as electrolytic plating, non-electrolytic plating, or thermal spraying can be used, for example.

The high-temperature fluid introducing part 14 and the high-temperature fluid discharging part 16 are disposed apart from each other in the front-rear direction so as to face each other. That is, the high-temperature fluid introducing part 14 and the high-temperature fluid discharging part 16 are disposed so as to cover, from sides in the front-rear direction, the high-temperature fluid flow passage part 12 disposed between the pair of low-temperature fluid flow passage parts 4 and 6. The high-temperature fluid introducing part 14 and the high-temperature fluid discharging part 16 have a pipe shape and are communicated with the high-temperature fluid flow passage part 12. The high-temperature fluid flows into the high-temperature fluid flow passage part 12 through the high-temperature fluid introducing part 14 and is discharged to an outside through the high-temperature fluid discharging part 16 after flowing through the high-temperature fluid flow passage part 12 in the front-rear direction (from a negative side toward a positive side of the X axis).

As illustrated in FIGS. 2 and 3, each of the thermoelectric modules 18 and 20 is disposed between the high-temperature fluid flow passage part 12 and the low-temperature fluid flow passage part 4 or 6. That is, the pair of thermoelectric modules 18 and 20 are disposed apart from each other in the up-down direction so as to face each other.

The thermoelectric module 18 on the upper side has a rectangular flat plate shape and is disposed so as to be sandwiched, from upper and lower sides, by the high-temperature fluid flow passage part 12 and the low-temperature fluid flow passage part 4 on the upper side. The thermoelectric module 18 on the upper side has a first main surface 18a that is in contact with (faces) a lower surface (a surface on the high-temperature fluid flow passage part 12 side) of the housing 22 of the low-temperature fluid flow passage part 4 on the upper side and a second main surface 18b that is in contact with (faces) the high-temperature fluid flow passage part 12. That is, the thermoelectric module 18 on the upper side has thermoelectric generators that generate electromotive force on the basis of a temperature difference between the high-temperature fluid flowing through the high-temperature fluid flow passage part 12 and the low-temperature fluid flowing through the low-temperature fluid flow passage part 4 on the upper side by the Seebeck effect.

Note that a heat transfer member (not illustrated) may be interposed between the first main surface 18a of the thermoelectric module 18 on the upper side and the low-temperature fluid flow passage part 4 on the upper side and/or between the second main surface 18b of the thermoelectric module 18 on the upper side and the high-temperature fluid flow passage part 12. The heat transfer member is, for example, a thermally-conductive sheet, thermally-conductive grease, or the like. This can increase efficiency of heat transfer from the low-temperature fluid flow passage part 4 on the upper side to the thermoelectric module 18 on the upper side and efficiency of heat transfer from the high-temperature fluid flow passage part 12 to the thermoelectric module 18 on the upper side.

The thermoelectric module 20 on the lower side has a rectangular flat plate shape and is disposed so as to be sandwiched, from upper and lower sides, by the high-temperature fluid flow passage part 12 and the low-temperature fluid flow passage part 6 on the lower side. The thermoelectric module 20 on the lower side has a first main surface 20a that is in contact with (faces) an upper surface (a surface on the high-temperature fluid flow passage part 12 side) of the housing 30 of the low-temperature fluid flow passage part 6 on the lower side and a second main surface 20b that is in contact with (faces) the high-temperature fluid flow passage part 12. That is, the thermoelectric module 20 on the lower side has thermoelectric generators that generate electromotive force on the basis of a temperature difference between the high-temperature fluid that flows through the high-temperature fluid flow passage part 12 and the low-temperature fluid that flows through the low-temperature fluid flow passage part 6 on the lower side by the Seebeck effect.

Note that a heat transfer member (not illustrated) may be interposed between the first main surface 20a of the thermoelectric module 20 on the lower side and the low-temperature fluid flow passage part 6 on the lower side and/or between the second main surface 20b of the thermoelectric module 20 on the lower side and the high-temperature fluid flow passage part 12. The heat transfer member is, for example, a thermally-conductive sheet, thermally-conductive grease, or the like. This can increase efficiency of heat transfer from low-temperature fluid flow passage part 6 on the lower side to the thermoelectric module 20 on the lower side and efficiency of heat transfer from the high-temperature fluid flow passage part 12 to the thermoelectric module 20 on the lower side.

The thermoelectric generators described above have, for example, a π structure. As illustrated in FIG. 4, in the thermoelectric generator 38 having the π structure, a P-type element 40 and an N-type element 42 are electrically connected in series with an electrode 44 interposed therebetween and are thermally arranged in parallel. The P-type element 40 and the N-type element 42 are covered with a pair of rectangular ceramic plates 46 from both sides. A first end of the P-type element 40 and a first end of the N-type element 42 are disposed on a high-temperature side, and a second end of the P-type element 40 and a second end of the N-type element 42 are disposed on a low-temperature side. Accordingly, a temperature difference is generated between the first end and the second end of the P-type element 40, and a temperature difference is generated between the first end and the second end of the N-type element 42. As a result, electromotive force is generated between a pair of terminals 48 and 50 of the thermoelectric generator 38. Electric power may be taken out by electrically connecting a load between the terminals 48 and 50.

### 1-2. Structure for Fixing Thermoelectric Conversion Unit

A structure for fixing the thermoelectric conversion unit 2 according to Embodiment 1 is described with reference to FIGS. 2, 3, and 5. FIG. 5 is a plan view illustrating the thermoelectric generator 38 according to Embodiment 1.

As illustrated in FIGS. 2 and 3, pairs (e.g., six pairs) of magnetic body parts 52 and 54 are used as a structure for fixing the thermoelectric conversion unit 2. Each of the magnetic body parts 52 and 54 has a bar shape as a whole.

The magnetic body part 52 has a main body 56 and a magnetic body 58. The main body 56 has a bar shape. The magnetic body 58 is attached to one end part of the main body 56. An engagement part 60 is provided at the other end part of the main body 56. The engagement part 60 has a tapered shape whose diameter gradually increases from one end part side to the other end part side of the main body 56. The main body 56 is, for example, made of a non-magnetic body such as stainless steel (SUS) or an aluminum alloy. The magnetic body 58 has, for example, a columnar shape and has, for example, a diameter of 5 mm to 10 mm. The magnetic body 58 is, for example, a permanent magnet such as a samarium-cobalt magnet, a neodymium magnet, an alnico magnet, or a ferrite magnet.

The magnetic body part 54 has a main body 62 and a magnetic body 64. The main body 62 has a bar shape. The magnetic body 64 is attached to one end part of the main body 62. An engagement part 66 is provided at the other end part of the main body 62. The engagement part 66 has a tapered shape whose diameter gradually increases from one end part side to the other end part side of the main body 62. The main body 62 is, for example, made of a non-magnetic body such as stainless steel (SUS) or an aluminum alloy. The magnetic body 64 has, for example, a columnar shape and has, for example, a diameter of 5 mm to 10 mm. The magnetic body 64 is, for example, a permanent magnet such as a samarium-cobalt magnet, a neodymium magnet, an alnico magnet, or a ferrite magnet.

The thermoelectric conversion unit 2 has insertion holes 68 (e.g., six insertion holes 68) into which the pairs of magnetic body parts 52 and 54 are inserted. The insertion holes 68 are formed in a manner such that an opening 70 provided in the low-temperature fluid flow passage part 4 on the upper side, a through-hole 72 provided in the thermoelectric module 18 on the upper side, a cylindrical part 74 provided in the high-temperature fluid flow passage part 12, a through-hole 76 provided in the thermoelectric module 20 on the lower side, and an opening 78 provided in the low-temperature fluid flow passage part 6 on the lower side are communicated with one another. The insertion holes 68 extend in the predetermined direction.

The opening 70 is provided in the housing 22 of the low-temperature fluid flow passage part 4 on the upper side and is opened toward the cylindrical part 74. An inner circumferential surface of the opening 70 has a tapered shape whose diameter gradually increases from a lower surface (a surface on the high-temperature fluid flow passage part 12 side) of the housing 22 to an upper surface (a surface on a side opposite to the high-temperature fluid flow passage part 12) of the housing 22. The magnetic body part 52 is inserted into the opening 70 from the magnetic body 58 side and extends in the predetermined direction. At this time, the engagement part 60 of the magnetic body part 52 is taper-engaged with the inner circumferential surface of the opening 70. That is, the magnetic body part 52 is disposed in the low-temperature fluid flow passage part 4 on the upper side.

The through-hole 72 passes through the thermoelectric module 18 on the upper side. Specifically, as illustrated in FIG. 5, the through-hole 72 passes through the thermoelectric generator 38 of the thermoelectric module 18 on the upper side so as to avoid the P-type element 40 and the N-type element 42 (see FIG. 4). The magnetic body part 52 is disposed in the through-hole 72. Note that although four through-holes 72 are provided in a single thermoelectric generator 38 in the example illustrated in FIG. 5, this is not restrictive, and any number of through-holes 72 may be provided in a single thermoelectric generator 38. In this case, the P-type element 40 and the N-type element 42 are electrically connected in series with the electrode 44 interposed therebetween and thermally arranged in parallel so as to avoid the through-hole 72.

The cylindrical part 74 is disposed along the predetermined direction so as to divide an inside of the high-temperature fluid flow passage part 12. The cylindrical part 74 has, for example, a cylindrical shape. At least a part of an inner circumferential surface of the cylindrical part 74 is covered with a heat insulating member 80. The heat insulating member 80 is, for example, made of glass wool, a ceramic, a resin, or the like. The high-temperature fluid flow passage part 12 has cylindrical parts 74, and the cylindrical parts 74 are substantially symmetrically disposed about a center of the high-temperature fluid flow passage part 12 on XY plan view. The magnetic body 58 of the magnetic body part 52 and the magnetic body 64 of the magnetic body part 54 are disposed in the cylindrical part 74. Note that a part of the cylindrical part 74 may be disposed in the through-hole 72 of the thermoelectric module 18 on the upper side and the through-hole 76 of the thermoelectric module 20 on the lower side.

The opening 78 is provided in the housing 30 of the low-temperature fluid flow passage part 6 on the lower side and is opened toward the cylindrical part 74. An inner circumferential surface of the opening 78 has a tapered shape whose diameter gradually increases from an upper surface (a surface on the high-temperature fluid flow passage part 12 side) of the housing 30 toward a lower surface (a surface on a side opposite to the high-temperature fluid flow passage part 12) of the housing 30. The magnetic body part 54 is inserted into the opening 78 from the magnetic body 64 side and extends in the predetermined direction. At this time, the engagement part 66 of the magnetic body part 54 is taper-engaged with the inner circumferential surface of the opening 78. That is, the magnetic body part 54 is disposed in the low-temperature fluid flow passage part 6 on the lower side.

The through-hole 76 passes through the thermoelectric module 20 on the lower side. The magnetic body part 54 is disposed in the through-hole 76.

The magnetic body 58 of the magnetic body part 52 and the magnetic body 64 of the magnetic body part 54 are disposed so that different magnetic poles face each other in the cylindrical part 74. For example, the magnetic body 58 of the magnetic body part 52 and the magnetic body 64 of the magnetic body part 54 are disposed so that an N pole of the magnetic body 58 of the magnetic body part 52 and an S pole of the magnetic body 64 of the magnetic body part 54 face each other. Note that a gap between the magnetic body 58 of the magnetic body part 52 and the magnetic body 64 of the magnetic body part 54 is, for example, approximately 1 mm.

The magnetic body 58 of the magnetic body part 52 and the magnetic body 64 of the magnetic body part 54 thus generate magnetic force (attraction force) that pulls the magnetic body 58 of the magnetic body part 52 and the magnetic body 64 of the magnetic body part 54 toward each other in the cylindrical part 74. At this time, since the engagement part 60 of the magnetic body part 52 and the opening 70 of the low-temperature fluid flow passage part 4 on the upper side are taper-engaged and the engagement part 66 of the magnetic body part 54 and the opening 78 of the low-temperature fluid flow passage part 6 on the lower side are taper-engaged, the low-temperature fluid flow passage part 4 on the upper side and the low-temperature fluid flow passage part 6 on the lower side sandwich the pair of thermoelectric modules 18 and 20 and the high-temperature fluid flow passage part 12 from both sides when the magnetic body 58 of the magnetic body part 52 and the magnetic body 64 of the magnetic body part 54 are pulled toward each other. As a result, thermal contact between the low-temperature fluid flow passage part 4 on the upper side and the thermoelectric module 18 on the upper side and thermal contact between the low-temperature fluid flow passage part 6 on the lower side and the thermoelectric module 20 on the lower side are promoted.

Here, POS satisfies the following formula (1) where POS is a pressure which the first main surface 18a of the thermoelectric module 18 on the upper side receives from the low-temperature fluid flow passage part 4 on the upper side:

10 kPa≤PoS≤1 MPa (1)

Similarly, PoS satisfies the above formula (1) where POS is a pressure which the first main surface 20a of the thermoelectric module 20 on the lower side receives from the low-temperature fluid flow passage part 6 on the lower side.

In a case where PoS is lower than 10 kPa, thermal contact between the low-temperature fluid flow passage part 4 on the upper side and the thermoelectric module 18 on the upper side and thermal contact between the low-temperature fluid flow passage part 6 on the lower side and the thermoelectric module 20 on the lower side are insufficient. On the other hand, in a case where POS is higher than 1 MPa, there is a risk of damaging the pair of thermoelectric modules 18 and 20.

### 1-3. Method of Using Thermoelectric Conversion Unit

Next, a method of using the thermoelectric conversion unit 2 according to Embodiment 1 is described with reference to FIGS. 1 and 3.

As illustrated in FIGS. 1 and 3, the low-temperature fluid flows into the low-temperature fluid flow passage 28 of the housing 22 of the low-temperature fluid flow passage part 4 on the upper side through the low-temperature fluid introducing part 24 and is discharged to an outside through the low-temperature fluid discharging part 26 after flowing through the low-temperature fluid flow passage 28. Heat of the low-temperature fluid flowing through the low-temperature fluid flow passage part 4 on the upper side transfers to the first main surface 18a of the thermoelectric module 18 on the upper side, and thereby the first main surface 18a of the thermoelectric module 18 on the upper side is cooled.

The low-temperature fluid flows into the low-temperature fluid flow passage 36 of the housing 30 of the low-temperature fluid flow passage part 6 on the lower side through the low-temperature fluid introducing part 32 and is discharged to an outside through the low-temperature fluid discharging part 34 after flowing through the low-temperature fluid flow passage 36. Heat of the low-temperature fluid that flows through the low-temperature fluid flow passage part 6 on the lower side transfers to the first main surface 20a of the thermoelectric module 20 on the lower side, and thereby the first main surface 20a of the thermoelectric module 20 on the lower side is cooled.

As illustrated in FIGS. 1 and 3, the high-temperature fluid flows into the high-temperature fluid flow passage part 12 through the high-temperature fluid introducing part 14 and is discharged to an outside through the high-temperature fluid discharging part 16 after flowing through the high-temperature fluid flow passage part 12 in the front-back direction. Heat of the high-temperature fluid that flows through the high-temperature fluid flow passage part 12 transfers to the second main surface 18b of the thermoelectric module 18 on the upper side and the second main surface 20b of the thermoelectric module 20 on the lower side through the heat transfer fins 37 and 39. This heats the second main surface 18b of the thermoelectric module 18 on the upper side and the second main surface 20b of the thermoelectric module 20 on the lower side.

In this way, a temperature difference (temperature gradient) is given in a thickness direction (the Z-axis direction) of the thermoelectric module 18 on the upper side so that a lower surface side becomes a high temperature and an upper surface side becomes a low temperature. As a result, the thermoelectric module 18 on the upper side generates power on the basis of the temperature difference between the lower surface side and the upper surface side (i.e., a temperature difference between the high-temperature fluid and the low-temperature fluid).

A temperature difference (temperature gradient) is given in the thickness direction (the Z-axis direction) of the thermoelectric module 20 on the lower side so that an upper surface side becomes a high temperature and a lower surface side becomes a low temperature. As a result, the thermoelectric module 20 on the lower side generates power on the basis of the temperature difference between the upper surface side and the lower surface side (i.e., a temperature difference between the high-temperature fluid and the low-temperature fluid).

### 1-4. Effects

In the present embodiment, as described above, the pair of magnetic body parts 52 and 54 are disposed in the low-temperature fluid flow passage part 4 on the upper side and the low-temperature fluid flow passage part 6 on the lower side, respectively. Therefore, the magnetic bodies 58 and 64 can be cooled by the low-temperature fluid that flows through the low-temperature fluid flow passage part 4 on the upper side and the low-temperature fluid flow passage part 6 on the lower side, and thereby a rise in temperature of the magnetic bodies 58 and 64 can be suppressed. This can suppress a decrease in magnetic moments of the magnetic bodies 58 and 64 and promotes thermal contact between the low-temperature fluid flow passage part 4 on the upper side and the thermoelectric module 18 on the upper side and thermal contact between the low-temperature fluid flow passage part 6 on the lower side and the thermoelectric module 20 on the lower side, thereby increasing power generation efficiency in the pair of thermoelectric modules 18 and 20.

The pair of low-temperature fluid flow passage parts 4 and 6, the high-temperature fluid flow passage part 12, and the pair of thermoelectric modules 18 and 20 are fixed to each other by utilizing magnetic force that pulls the magnetic body 58 of the magnetic body part 52 and the magnetic body 64 of the magnetic body part 54 toward each other. This produces flexibility in relative positional relationship among the pair of low-temperature fluid flow passage parts 4 and 6, the high-temperature fluid flow passage part 12, and the pair of thermoelectric modules 18 and 20. As a result, for example, even in a case where external vibration, thermal shock, or the like is applied to the thermoelectric conversion unit 2, the pair of low-temperature fluid flow passage parts 4 and 6, the high-temperature fluid flow passage part 12, and the pair of thermoelectric modules 18 and 20 are displaced relative to each other. This absorbs stress applied to the pair of thermoelectric modules 18 and 20, thereby suppressing damage of the pair of thermoelectric modules 18 and 20.

### 1-5. Modification of High-Temperature Fluid Flow Passage Part

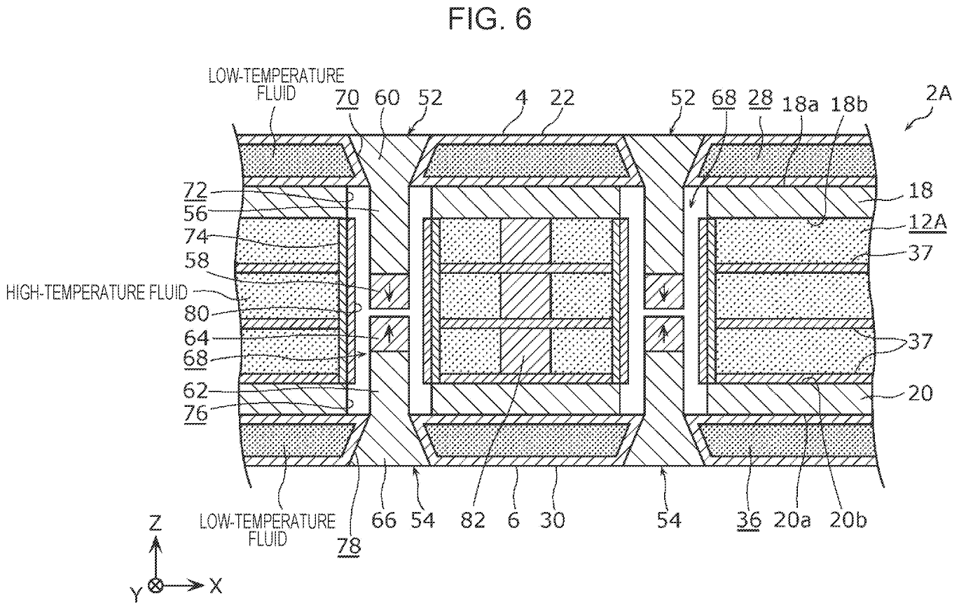

A configuration of a high-temperature fluid flow passage part 12A of a thermoelectric conversion unit 2A according to a modification of Embodiment 1 is described with reference to FIG. 6. FIG. 6 is a cross-sectional view of a substantial part of the thermoelectric conversion unit 2A according to the modification of Embodiment 1.

As illustrated in FIG. 6, in the thermoelectric conversion unit 2A according to the modification of Embodiment 1, the high-temperature fluid flow passage part 12A has heat transfer fins 37 having a plate shape and heat transfer fins 82 having a pin shape (bar shape). In FIG. 6, a single heat transfer fin 82 is illustrated for convenience of description.

Each of the heat transfer fins 82 has, for example, a columnar shape and is disposed along the predetermined direction. Each of the heat transfer fins 82 is fixed to the heat transfer fins 37. Heat of the high-temperature fluid that flows through the high-temperature fluid flow passage part 12A transfers to the pair of thermoelectric modules 18 and 20 through the heat transfer fins 37 and the heat transfer fins 82.

Note that although the high-temperature fluid flow passage part 12A has the heat transfer fins 37 having a corrugated plate shape and the heat transfer fins 82 having a pin shape in the present modification, this is not restrictive, the high-temperature fluid flow passage part 12A may have heat transfer fins 39 having a flat plate shape instead of the heat transfer fins 37 having a corrugated plate shape or may have only the heat transfer fins 82 having a pin shape.

### 1-6. Modification of Thermoelectric Module

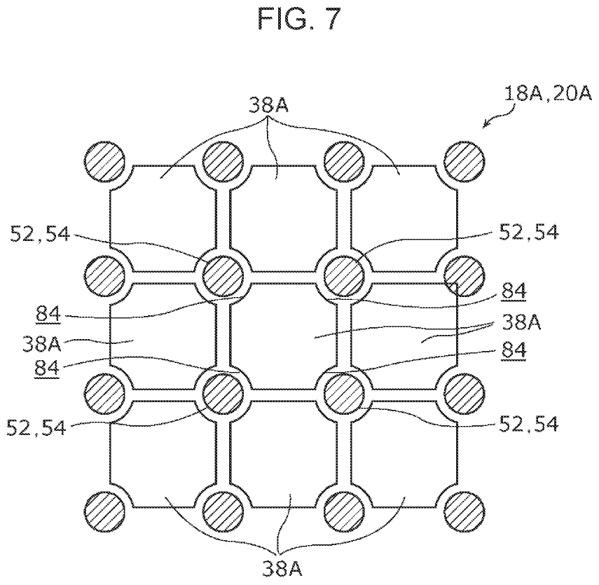

A configuration of a pair of thermoelectric modules 18A and 20A according to a modification of Embodiment 1 is described with reference to FIG. 7. FIG. 7 is a schematic view for explaining a configuration of the thermoelectric module 18A (20A) according to the modification of Embodiment 1.

As illustrated in FIG. 7, in the pair of thermoelectric modules 18A and 20A according to the modification of Embodiment 1, rectangular thermoelectric generators 38A are arranged in a matrix. Each of four corners of each of the thermoelectric generators 38A has a semi-circular cut-out part 84. Accordingly, a substantially circular insertion hole through which the magnetic body part 52 or 54 is to be inserted is formed by the cut-out parts 84 of four thermoelectric generators 38A that are adjacent to each other (arranged in two rows and two columns).

With this configuration, the thermoelectric generators 38A can be arranged without a gap, and thermoelectric generation capability of the pair of thermoelectric modules 18A and 20A can be increased. Note that in the present modification, a through-hole may be formed in each of the pair of thermoelectric modules 18A and 20A, as in the above case.

### Embodiment 2

### 2-1. Structure for Fixing Thermoelectric Conversion Unit

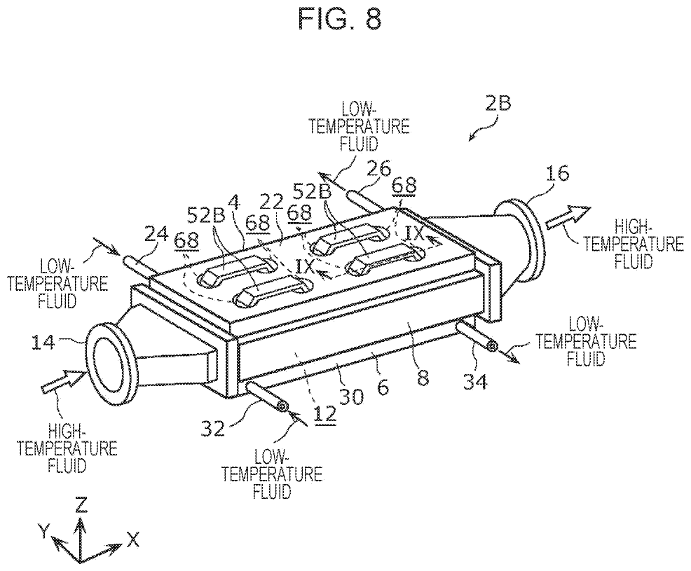

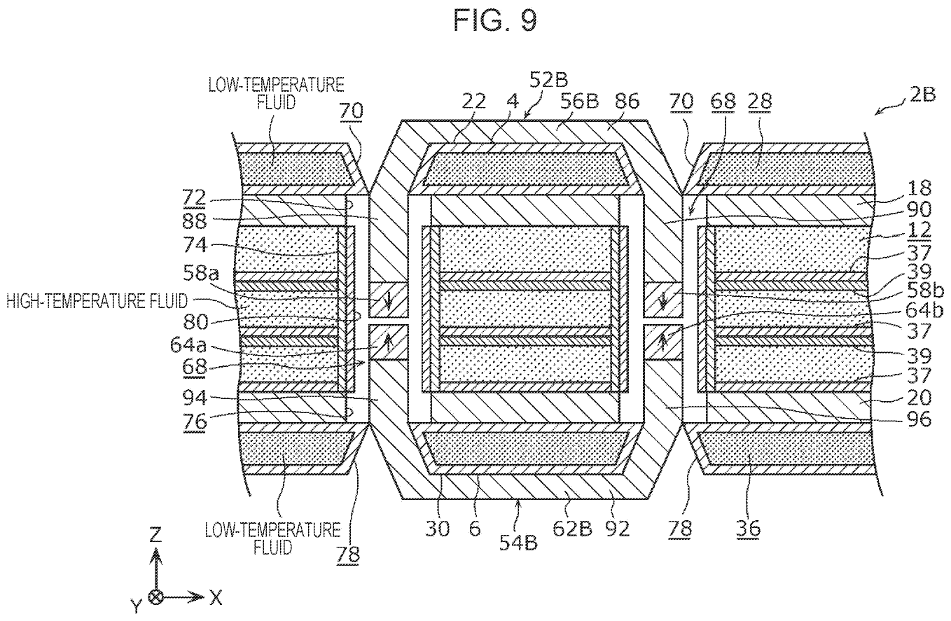

A structure for fixing a thermoelectric conversion unit 2B according to Embodiment 2 is described with reference to FIGS. 8 and 9. FIG. 8 is a perspective view illustrating the thermoelectric conversion unit 2B according to Embodiment 2. FIG. 9 is a cross-sectional view of a substantial part of the thermoelectric conversion unit 2B according to Embodiment 2 taken along line IX-IX of FIG. 8. Note that in each of the embodiments below, constituent elements identical to those in Embodiment 1 are given identical reference signs, and repeated description thereof is omitted.

As illustrated in FIGS. 8 and 9, pairs (e.g., four pairs) of magnetic body parts 52B and 54B are used as a structure for fixing the thermoelectric conversion unit 2B according to Embodiment 2. Each of the magnetic body parts 52B and 54B has a substantially U shape as a whole.

The magnetic body part 52B has a main body 56B and a pair of magnetic bodies 58a and 58b. The main body 56B has a pressing part 86 and a pair of insertion parts 88 and 90 that extend from both end parts of the pressing part 86 so as to face each other. The pair of magnetic bodies 58a and 58b are attached to leading end parts of the pair of insertion parts 88 and 90, respectively.

The magnetic body part 54B has a main body 62B and a pair of magnetic bodies 64a and 64b. The main body 62B has a pressing part 92 and a pair of insertion parts 94 and 96 that extend from both end parts of the pressing part 92 so as to face each other. The pair of magnetic bodies 64a and 64b are attached to leading end parts of the pair of insertion parts 94 and 96, respectively.

The thermoelectric conversion unit 2B has insertion holes 68 (e.g., eight insertion holes 68) into which the pairs of magnetic body parts 52B and 54B are inserted. The pair of insertion parts 88 and 90 of the magnetic body part 52B are inserted into a pair of insertion holes 68 (a pair of openings 70) that are adjacent in the front-rear direction (the X-axis direction) of a low-temperature fluid flow passage part 4 on the upper side, respectively. At this time, the pair of insertion parts 88 and 90 extend along the predetermined direction. The pressing part 86 extends along a direction orthogonal to (crossing) the predetermined direction and makes contact with an upper surface of a housing 22 of the low-temperature fluid flow passage part 4 on the upper side.

The pair of insertion parts 94 and 96 of the magnetic body part 54B are inserted into a pair of insertion holes 68 (a pair of openings 78) that are adjacent in the front-rear direction of a low-temperature fluid flow passage part 6 on the lower side, respectively. At this time, the pair of insertion parts 94 and 96 extend along the predetermined direction. The pressing part 92 extends along a direction orthogonal to (crossing) the predetermined direction and makes contact with a lower surface of a housing 30 of the low-temperature fluid flow passage part 6 on the lower side.

The magnetic body 58a of the magnetic body part 52B and the magnetic body 64a of the magnetic body part 54B are disposed so that different magnetic poles face each other in the cylindrical part 74. The magnetic body 58b of the magnetic body part 52B and the magnetic body 64b of the magnetic body part 54B are disposed so that different magnetic poles face each other in the cylindrical part 74.

As a result, the magnetic body 58a of the magnetic body part 52B and the magnetic body 64a of the magnetic body part 54B generate magnetic force that pulls the magnetic body 58a and the magnetic body 64a toward each other in the cylindrical part 74. The magnetic body 58b of the magnetic body part 52B and the magnetic body 64b of the magnetic body part 54B generate magnetic force that pulls the magnetic body 58b and the magnetic body 64b toward each other in the cylindrical part 74. At this time, the pressing part 86 of the magnetic body part 52B presses the low-temperature fluid flow passage part 4 on the upper side toward a thermoelectric module 18 on the upper side, and the pressing part 92 of the magnetic body part 54B presses the low-temperature fluid flow passage part 6 on the lower side toward a thermoelectric module 20 on the lower side. As a result, the low-temperature fluid flow passage part 4 on the upper side and the low-temperature fluid flow passage part 6 on the lower side sandwich the pair of thermoelectric modules 18 and 20 and the high-temperature fluid flow passage part 12 from both sides.

In the present embodiment, a large contact area between the pressing part 86 of the magnetic body part 52B and the low-temperature fluid flow passage part 4 on the upper side can be secured, and therefore a surface pressure applied to the thermoelectric module 18 on the upper side can be kept substantially uniform. This can suppress occurrence of stress unevenness in the thermoelectric module 18 on the upper side.

Similarly, a large contact area between the pressing part 92 of the magnetic body part 54B and the low-temperature fluid flow passage part 6 on the lower side can be secured, and therefore a surface pressure applied to the thermoelectric module 20 on the lower side can be kept substantially uniform. This can suppress occurrence of stress unevenness in the thermoelectric module 20 on the lower side.

### 2-2. Modification 1

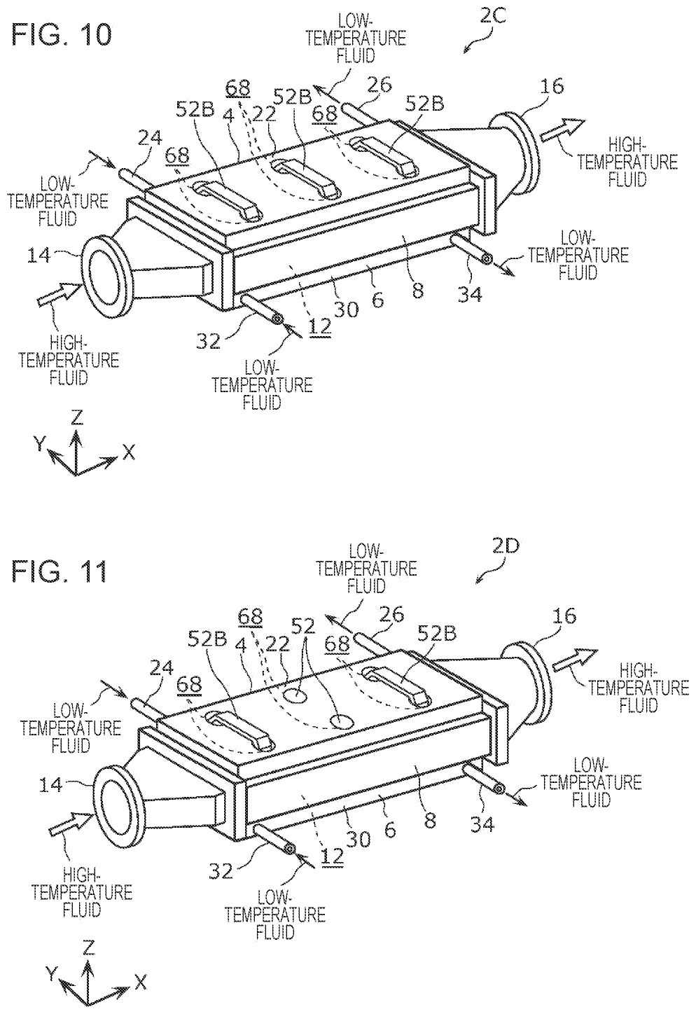

A structure for fixing a thermoelectric conversion unit 2C according to Modification 1 of Embodiment 2 is described with reference to FIG. 10. FIG. 10 is a perspective view illustrating the thermoelectric conversion unit 2C according to Modification 1 of Embodiment 2.

As illustrated in FIG. 10, pairs (e.g., three pairs) of magnetic body parts 52B and 54B (see FIG. 9) are used as a structure for fixing the thermoelectric conversion unit 2C according to Modification 1 of Embodiment 2. The thermoelectric conversion unit 2C has insertion holes 68 (e.g., six insertion holes 68) through which the pairs of magnetic body parts 52B and 54B are inserted.

The pair of insertion parts 88 and 90 (see FIG. 9) of the magnetic body part 52B are inserted into a pair of insertion holes 68 that are adjacent in the left-right direction (the Y-axis direction) of the low-temperature fluid flow passage part 4 on the upper side, respectively. The pair of insertion parts 94 and 96 (see FIG. 9) of the magnetic body part 54B are inserted into a pair of insertion hole 68 that are adjacent in the left-right direction of the low-temperature fluid flow passage part 6 on the lower side, respectively.

Therefore, effects similar to those described above can be obtained in the present modification.

### 2-3. Modification 2

A structure for fixing a thermoelectric conversion unit 2D according to Modification 2 of Embodiment 2 is described with reference to FIG. 11. FIG. 11 is a perspective view illustrating the thermoelectric conversion unit 2D according to Modification 2 of Embodiment 2.

As illustrated in FIG. 11, pairs (e.g., two pairs) of magnetic body parts 52 and 54 (scc FIG. 3) and pairs (e.g., two pairs) of magnetic body parts 52B and 54B (see FIG. 9) are used as a structure for fixing the thermoelectric conversion unit 2D according to Modification 2 of Embodiment 2. The thermoelectric conversion unit 2D has insertion holes 68 (e.g., six insertion holes 68) through which the pairs of magnetic body parts 52 and 54 and the pairs of magnetic body parts 52B and 54B are inserted.

In the present modification, the pair of magnetic body parts 52B and 54B at the center of Modification 2 is replaced with the pairs of magnetic body parts 52 and 54. Even with this configuration, effects similar to those described above can be obtained.

### Embodiment 3

### 3-1. Structure for Fixing Thermoelectric Conversion Unit

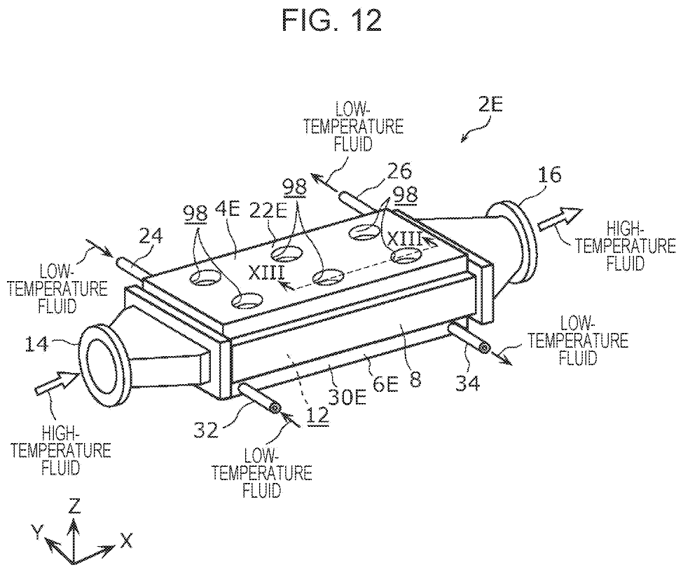

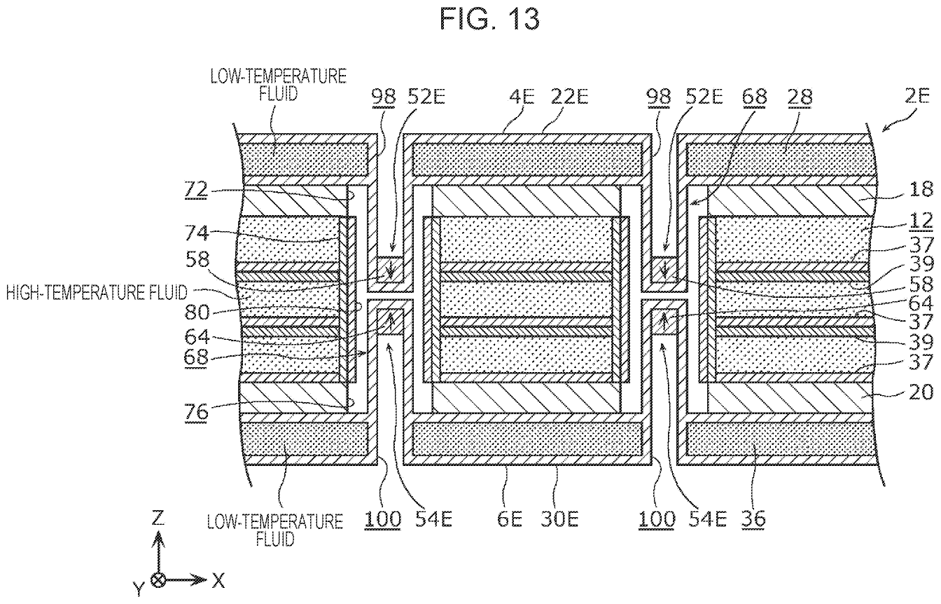

A structure for fixing a thermoelectric conversion unit 2E according to Embodiment 3 is described with reference to FIGS. 12 and 13. FIG. 12 is a perspective view illustrating the thermoelectric conversion unit 2E according to Embodiment 3. FIG. 13 is a cross-sectional view of a substantial part of the thermoelectric conversion unit 2E according to Embodiment 3 taken along line XIII-XIII of FIG. 12.

In the structure for fixing the thermoelectric conversion unit 2E according to Embodiment 3, a housing 22E of a low-temperature fluid flow passage part 4E on the upper side has a groove part 98 that protrudes downward (toward a negative side of the Z axis) toward a cylindrical part 74, and a housing 30E of a low-temperature fluid flow passage part 6E on the lower side has a groove part 100 that protrudes upward (toward a positive side of the Z axis) toward the cylindrical part 74. The groove parts 98 and 100 have, for example, a circular shape in XY plan view. The groove parts 98 and 100 are disposed so as to face each other in the cylindrical part 74.

A magnetic body part 52E has a magnetic body 58 and does not have a main body described above. The magnetic body 58 is disposed in the groove part 98 of the low-temperature fluid flow passage part 4E on the upper side so as to be located on a surface of the low-temperature fluid flow passage part 4E on the upper side. The magnetic body part 54E has a magnetic body 64 and does not have a main body described above. The magnetic body 64 is disposed in the groove part 100 of the low-temperature fluid flow passage part 6E on the lower side so as to be located on a surface of the low-temperature fluid flow passage part 6E on the lower side.

The magnetic body 58 disposed in the groove part 98 and the magnetic body 64 disposed in the groove part 100 generate magnetic force that pulls the magnetic body 58 and the magnetic body 64 toward each other in the cylindrical part 74. As a result, the low-temperature fluid flow passage part 4E on the upper side and the low-temperature fluid flow passage part 6E on the lower side sandwich a pair of thermoelectric modules 18 and 20 and a high-temperature fluid flow passage part 12 from both sides. Therefore, in the present embodiment, effects similar to those described above can be obtained.

Note that bottom parts of the groove parts 98 and 100 are, for example, preferably made of a ceramic, glass, or the like so as not to absorb magnetic force from the magnetic bodies 58 and 64.

### 3-2. Modification

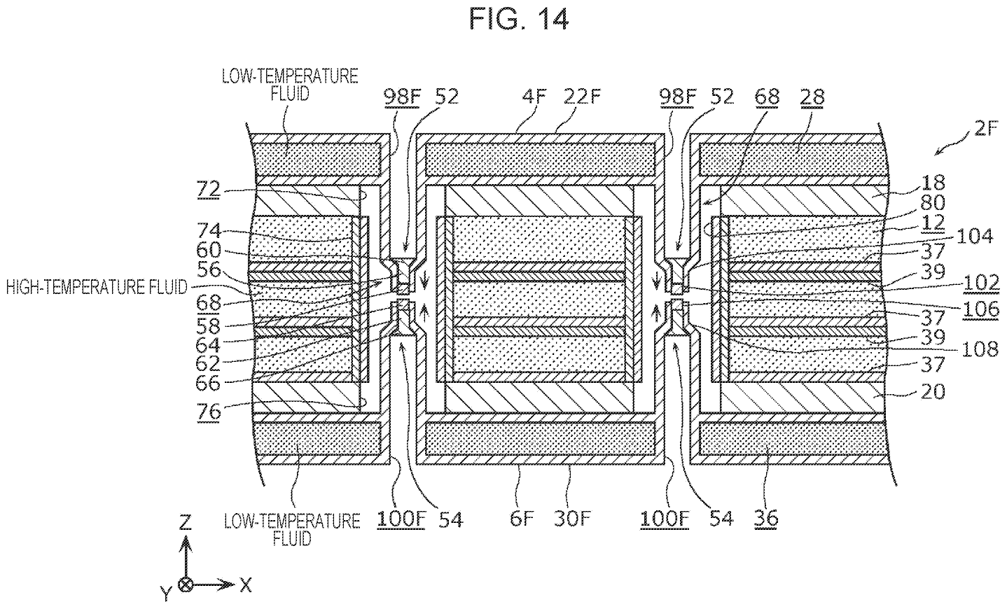

A structure for fixing a thermoelectric conversion unit 2F according to a modification of Embodiment 3 is described with reference to FIG. 14. FIG. 14 is a cross-sectional view of a substantial part of the thermoelectric conversion unit 2F according to the modification of Embodiment 3.

As illustrated in FIG. 14, in the thermoelectric conversion unit 2F according to the modification of Embodiment 3, a bottom part of a groove part 98F provided in a housing 22F of a low-temperature fluid flow passage part 4F on the upper side has an opening 102 opened toward the cylindrical part 74. A tapered part 104 is provided slightly above the opening 102 of the groove part 98F.

A magnetic body part 52 is inserted into the groove part 98F from a magnetic body 58 side and thus extends in the predetermined direction. At this time, an engagement part 60 of the magnetic body part 52 is taper-engaged with an inner peripheral surface of the tapered part 104 of the groove part 98F. The magnetic body 58 of the magnetic body part 52 is inserted into the opening 102 of the groove part 98F.

A bottom part of a groove part 100F provided in a housing 30F of a low-temperature fluid flow passage part 6F on the lower side has an opening 106 opened toward the cylindrical part 74. A tapered part 108 is provided slightly below the opening 106 of the groove part 100F.

A magnetic body part 54 is inserted into the groove part 100F from a magnetic body 64 side and thus extends in the predetermined direction. At this time, an engagement part 66 of the magnetic body part 54 is taper-engaged with an inner peripheral surface of the tapered part 108 of the groove part 100F. The magnetic body 64 of the magnetic body part 54 is inserted into the opening 106 of the groove part 100F.

The magnetic body 58 disposed in the groove part 98F and the magnetic body 64 disposed in the groove part 100F generate magnetic force that pulls the magnetic body 58 and the magnetic body 64 toward each other in the cylindrical part 74. At this time, since the engagement part 60 of the magnetic body part 52 and the tapered part 104 of the groove part 98F are taper-engaged and the engagement part 66 of the magnetic body part 54 and the tapered part 108 of the groove part 100F are taper-engaged, the low-temperature fluid flow passage part 4F on the upper side and the low-temperature fluid flow passage part 6F on the lower side sandwich the pair of thermoelectric modules 18 and 20 and the high-temperature fluid flow passage part 12 from both sides when the magnetic body 58 of the magnetic body part 52 and the magnetic body 64 of the magnetic body part 54 are pulled toward each other. Therefore, in the present embodiment, effects similar to those described above can be obtained.

### Embodiment 4

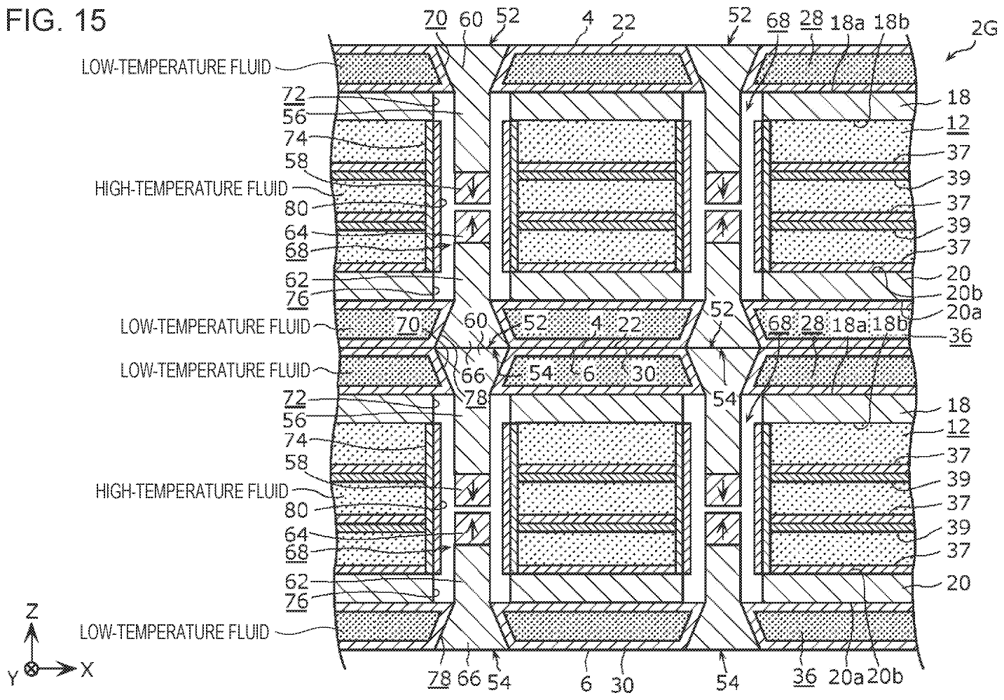

A configuration of a thermoelectric conversion unit 2G according to Embodiment 4 is described with reference to FIG. 15. FIG. 15 is a cross-sectional view of a substantial part of the thermoelectric conversion unit 2G according to Embodiment 4.

As illustrated in FIG. 15, in the thermoelectric conversion unit 2G according to Embodiment 4, two pairs of thermoelectric modules 18 and 20 are stacked in the up-down direction (the Z-axis direction). Such a stack structure can make the thermoelectric conversion unit 2G compact. Such a stack structure can further increase power generation efficiency per thermoelectric conversion unit 2G.

Note that although two pairs of thermoelectric modules 18 and 20 are stacked in the up-down direction in the present embodiment, this is not restrictive, and three or more pairs of thermoelectric modules 18 and 20 may be stacked.

### Other Embodiments

Although a thermoelectric conversion unit according to one or more aspects of the present disclosure has been described above on the basis of the embodiments, the present disclosure is not limited to the embodiments. Various modifications of the present embodiment which a person skilled in the art can think of may be also encompassed within one or more aspects of the present disclosure without departing from the spirit of the present disclosure.

Although the high-temperature fluid is exhaust gas and the low-temperature fluid is cool water or cool air in the above embodiments, this is not restrictive, and the high-temperature fluid and the low-temperature fluid may be any liquid or gas.

A thermoelectric conversion unit according to the present disclosure is, for example, used for a power generator that generates power by utilizing thermal energy of exhaust gas discharged from an automobile, a factory, or the like or a small-sized mobile power generator.

What is claimed is:

1. A thermoelectric conversion unit comprising:
a pair of first fluid flow passage parts that face each other and through which a first fluid flows;
a second fluid flow passage part that is disposed between the pair of first fluid flow passage parts and through which a second fluid having a higher temperature than the first fluid flows;
a pair of thermoelectric modules each of which is disposed between a corresponding one of the first fluid flow passage parts that constitute the pair of first fluid flow passage parts and the second fluid flow passage part and generates electromotive force on a basis of a temperature difference between the first fluid and the second fluid; and
a pair of magnetic body parts that are disposed inside of or on a surface of the pair of first fluid flow passage parts, respectively,
wherein
each of the magnetic body parts has a magnetic body, and
the magnetic bodies of the pair of magnetic body parts are disposed so that different magnetic poles face each other, and generate magnetic force that pulls the magnetic bodies toward each other.

2. The thermoelectric conversion unit according to claim 1, further comprising a cylindrical part that divides at least an inside of the second fluid flow passage part along a predetermined direction pointing from one of the first fluid flow passage parts to an other one of the first fluid flow passage parts,
wherein the magnetic bodies of the pair of magnetic body parts generate the magnetic force in the cylindrical part.

3. The thermoelectric conversion unit according to claim 2, wherein
the magnetic bodies of the pair of magnetic body parts are disposed in the cylindrical part.

4. The thermoelectric conversion unit according to claim 2, wherein
cylindrical parts are provided as the cylindrical part; and
the cylindrical parts are substantially symmetrically disposed about a center of the second fluid flow passage part.

5. The thermoelectric conversion unit according to claim 2, wherein
each of the first fluid flow passage parts has a groove part that protrudes toward the cylindrical part; and
each of the magnetic bodies of the pair of magnetic body parts is disposed in the groove part so as to be located on a surface of a corresponding one of the first fluid flow passage parts.

6. The thermoelectric conversion unit according to claim 2, wherein
each of the first fluid flow passage parts has an opening opened toward the cylindrical part; and
each of the magnetic body parts is inserted into the opening.

7. The thermoelectric conversion unit according to claim 6, wherein
each of the magnetic body parts has a bar shape and extends along the predetermined direction;
the magnetic body is disposed at one end part of each of the magnetic body parts; and
an other end part of each of the magnetic body parts is engaged with the opening.

8. The thermoelectric conversion unit according to claim 6, wherein
one pair of openings are provided as the opening;
each of the magnetic body parts has a pressing part that extends along a direction that crosses the predetermined direction and a pair of insertion parts that extend from both end parts of the pressing part along the predetermined direction and face each other;
the pair of insertion parts are inserted into the pair of openings, respectively;
the magnetic body is disposed in each of the insertion parts; and
the pressing part presses a corresponding one of the first fluid flow passage parts toward a corresponding one of the thermoelectric modules.

9. The thermoelectric conversion unit according to claim 2, wherein
each of the thermoelectric modules has a through-hole that passes through the thermoelectric module; and
a corresponding one of the magnetic body parts, the cylindrical part, or the corresponding one of the magnetic body parts and the cylindrical part is/are disposed in the through-hole.

10. The thermoelectric conversion unit according to claim 2, wherein
as the pair of thermoelectric modules, pairs of thermoelectric modules are stacked in the predetermined direction.

11. The thermoelectric conversion unit according to claim 2, wherein
at least a part of an inner circumferential surface of the cylindrical part is covered with a heat insulating member.

12. The thermoelectric conversion unit according to claim 11, wherein
the heat insulating member is made of at least one of glass wool, a ceramic, or a resin.

13. The thermoelectric conversion unit according to claim 2, wherein
the second fluid flow passage part has a heat transfer fin having a pin shape disposed along the predetermined direction, heat transfer fins having a plate shape that face each other along the predetermined direction, or the heat transfer fin having a pin shape and the heat transfer fins having a plate shape.

14. The thermoelectric conversion unit according to claim 1, wherein
each of the thermoelectric modules has a first main surface that faces a corresponding one of the first fluid flow passage parts and a second main surface that faces the second fluid flow passage part; and
PoS satisfies the following formula (1):
10 kPa≤PoS≤1 MPa (1)
where PoS is a pressure which the first main surface of each of the thermoelectric modules receives from a corresponding one of the first fluid flow passage parts.

15. The thermoelectric conversion unit according to claim 1, wherein
each of the thermoelectric modules has a first main surface that faces a corresponding one of the first fluid flow passage parts and a second main surface that faces the second fluid flow passage part; and
a heat transfer member is interposed between each of the first fluid flow passage parts and the first main surface, between the second fluid flow passage part and the second main surface, or between each of the first fluid flow passage parts and the first main surface and between the second fluid flow passage part and the second main surface.

16. The thermoelectric conversion unit according to claim 15, wherein
the heat transfer member is a thermally-conductive sheet, thermally-conductive grease, or the thermally-conductive sheet and the thermally-conductive grease.

17. The thermoelectric conversion unit according to claim 1, wherein
the magnetic body is a permanent magnet.

18. The thermoelectric conversion unit according to claim 17, wherein
the permanent magnet is at least one of a samarium-cobalt magnet, a neodymium magnet, an alnico magnet, or a ferrite magnet.

19. A method of using a thermoelectric conversion unit, the thermoelectric conversion unit including:
a pair of first fluid flow passage parts that face each other and through which a first fluid flows;
a second fluid flow passage part that is disposed between the pair of first fluid flow passage parts and through which a second fluid having a higher temperature than the first fluid flows;
a pair of thermoelectric modules each of which is disposed between a corresponding one of the first fluid flow passage parts that constitute the pair of first fluid flow passage parts and the second fluid flow passage part and generates electromotive force on a basis of a temperature difference between the first fluid and the second fluid; and
a pair of magnetic body parts that are disposed inside of or on a surface of the pair of first fluid flow passage parts, respectively,
each of the magnetic body parts having a magnetic body, and
the magnetic bodies of the pair of magnetic body parts being disposed so that different magnetic poles face each other, and generate magnetic force that pulls the magnetic bodies toward each other,
the method comprising:
transferring heat of the second fluid to each of the thermoelectric modules; and
generating the electromotive force on a basis of the temperature difference by giving the temperature difference to each of the thermoelectric modules.

20. A thermoelectric conversion unit comprising:
a first flow passage through which a first fluid flows;
a second flow passage that faces the first flow passage and through which a second fluid flows;
a third flow passage that is provided between the first flow passage and the second flow passage and through which a third fluid flows, a third temperature of the third fluid being higher than a first temperature of the first fluid and the third temperature being higher than a second temperature of the second fluid;
a first thermoelectric module that is provided between the first flow passage and the third flow passage and generates an electromotive voltage on a basis of a temperature difference between the first temperature and the third temperature;
a second thermoelectric module that is provided between the second flow passage and the third flow passage and generates an electromotive voltage on a basis of a temperature difference between the second temperature and the third temperature; and
a first magnetic body and a second magnetic body that are provided between the first flow passage and the second flow passage,
wherein
the first flow passage and the first magnetic body are connected by using a first member,
the second flow passage and the second magnetic body are connected by using a second member,
a first portion of the first magnetic body faces a second portion of the second magnetic body,
a magnetic pole of the first portion is different from a magnetic pole of the second portion,
the third flow passage does not include the first magnetic body, and
the third flow passage does not include the second magnetic body.
